(19) United States
(12) Patent Application Publication
(10) Pub. No.: US 2011/0089031 A1
(43) Pub. Date: Apr. 21, 2011

(54) Sputtering System with Normal Target and Slant Targets on the Side

(75) Inventors: Chao-Hsi Cheng, Taipei City (TW); Wei-Yen Fu, Sijhih City (TW)

(73) Assignee: SUNTEK PRECISION CORP., Sijhih City (TW)

(21) Appl. No.: 12/903,383

(22) Filed: Oct. 13, 2010

(30) Foreign Application Priority Data
Oct. 16, 2009 (TW) 98135072

(51) Int. Cl. C23C 14/35; C23C 14/04

(52) U.S. Cl. 204/298.41

(57) ABSTRACT

A sputtering system aimed for sputtering workpieces that have non-planar surfaces, such as concaves, pillars, and steps of a case of a laptop. The sputtering system comprises a sputtering chamber including a carrier, a first sputtering source, and a second sputtering source. The first sputtering source is located over the carrier main to sputter planar portion of the workpiece. The second sputtering source is inclined at an angle so as to sputter the vertical portion of the workpiece.

### FIELD OF THE INVENTION

The present invention relates to a sputtering system with a normal target and slant targets for forming a film on a workpiece having 3-dimensional surfaces by sputtering.

### BACKGROUND OF THE INVENTION

Nowadays, electronic products such as laptops, cellular phones, MP3s have become immensely popular. When customers are choosing from a wide variety of affordable products, the weight, appearance, and even touch and texture of the products are the important factors in addition to the functions to consider.

As engineering plastic can be easily molded by injecting molding process, cases of electronic products are usually made of engineering plastics. However, the texture and touch of engineering plastics are not good enough to meet customer's demands. Besides, such materials are incapable of preventing electronic members enclosed in the case from penetrating of electromagnetic waves (EM waves) which come from universe and often interfere normal functions of an electronic product. The product with an extra protective coating to shield electromagnetic interference (EMI) and to give it a better appearance is demanded.

The metal layer is known to have capability of blocking EMI and make the plastic case with metal shine. Thus, the plastic cases coated with a metal layer are popular and welcomed. In the past, single metal layer deposited on the plastic is usually implemented by spray or electroplating. However, with the rapid development of sputtering techniques, the metal layer is preferred deposited by sputtering in recently years. The method of depositing the metal layer by sputtering system comprises generating plasmas by producing gas discharges in a low vacuum atmosphere and making cations of the plasma collide against a target on a negative electrode that is called a sputtering electrode, so that the particles sputtered by the collision are deposited onto the substrate and form a film. Depending on whether a workpiece is hanged on or placed on a worktable during sputtering, the sputtering systems are classified as a vertical and a horizontal sputtering system. However, no matter what type is, the “shadow effect” is often found for some recesses, pillars, and stairs of the workpiece. The films are not uniform.

For example, a floor of the workpiece after sputtering is usually to have a thickness double more than that of the sidewall, practically, to a vertical sidewall. The bad uniformity is found at areas such as boss bolt, the recesses or the stairs. The non-uniform may cause some regions without having a sufficient film-thickness to block EMI, especially for the workpiece having many boss bolts. It is thus an object of the present invention is to solve aforementioned inferior during sputtering.

### BRIEF SUMMARY OF THE INVENTION

The present invention meets the need by providing a sputtering system to deposit films onto a 3-dimensional workpiece. In accordance with one embodiment of the present invention, a sputtering system is provided. The sputtering system comprises a vacuum chamber having a carrier for supporting a workpiece having a first planar surface and a second surface which substantially perpendicular to the first planar surface; a first sputtering source being sputtered by plasma to deposit the films mainly onto the first planar surface.

A second sputtering source composed of a plurality of second targets which are assembled to form a round corner rectangular loop which surrounds the first sputtering source. The second sputtering source having a predetermined height larger than the height of the second surface is set inclines inward a predetermined angle so that the second sputtering source can be served as a normal target of the second surface for improving the coated film uniformity.

Besides, an upper and a lower magnet sets disposed, respectively, on an upper and a lower sidewalls of the second targets having a shape of loop so as to generate a magnetic path which is unique and enclosed around the second targets.

The sputtering system further comprises two first magnets, one of which surrounds an inner sidewall of the first sputtering source and the other surrounds an outer sidewall.

The second sputtering source is composed of four rectangular targets, each of which is disposed on a target seat, the four rectangular targets surrounded the first sputtering source but have an interval in between. Two insulator sheets are placed in diagonal positions of the intervals for reactive sputtering.

The second sputtering source, whose shape is closed-loop, is composed of four rectangular targets as edges and four round corner targets connected therebetween as four corners.

The sputtering system further comprises a mask with a predetermined pattern so as to deposit the films having a corresponding pattern onto the workpiece.

The sputtering system further comprises the rotating device to rotate the workpiece during sputtering process so that different kinds of materials are mixed well to deposit a composite or alloy film.

Other and further features, advantages, and benefits of the invention will become apparent in the following description taken in conjunction with the following drawings. It is to be understood that the foregoing general description and following detailed description are exemplary and explanatory but are not to be restrictive of the invention.

### BRIEF DESCRIPTION OF THE DRAWINGS

Other features and advantages of this invention will become more apparent in the following detailed description of the preferred embodiments of this invention, with reference to the accompanying drawings, in which:

FIG. 1A illustrates a plan view of the sputtering system of one embodiment of the present invention;

FIG. 1B illustrates a cross-sectional view, viewing from a line A-A′ cut from FIG. 1A of a sputtering system of one embodiment of the present invention;

FIG. 2 illustrates the workpiece having non-planar surface;

FIG. 3A illustrates a plan view of the sputtering system of another embodiment of the present invention;

FIG. 3B illustrates a cross-sectional view, viewing from a line A-A′ cut from FIG. 1A of a sputtering system of another embodiment of the present invention;

FIG. 3C illustrates the schematic perspective view of the first sputtering source and the second sputtering source of another embodiment of the present invention; and

FIG. 4 illustrates the schematic topside view of the multi-chamber sputtering system of another embodiment of the present invention.

### DETAILED DESCRIPTION THE INVENTION

Reference will now be made in detail to the preferred embodiments of the present invention, examples of which are illustrated in accompany drawings.

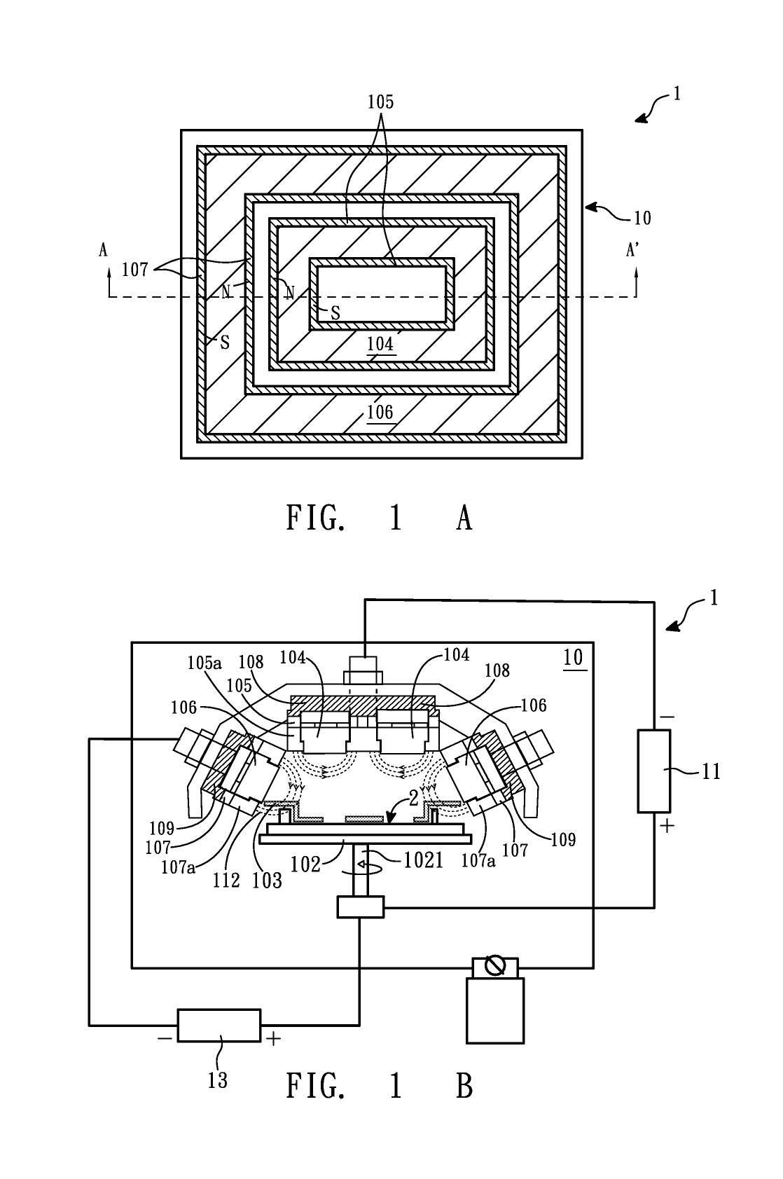

Please refer to FIGS. 1A and 1B, which are, respectively, a plan view and a cross-sectional view, viewing from a line A-A′ cut from FIG. 1A of a sputtering system in accordance with a preferred embodiment of the present invention. The sputtering system 1 is provided for depositing a metal film on a 3-dimensional workpiece having non-planar surfaces, especially, vertical surface.

The sputtering system 1 comprises a vacuum chamber 10 having at least a workpiece carrier 102, a first sputtering source 104 and a second sputtering source 106.

In a preferred embodiment of the present invention, the workpiece carrier 102 is optional and a carrier belt may be served as a substitute to carry workpieces. A fasten member (not shown) may use to fix the workpiece 2. To avoid “shadow effect” one workpiece per batch is usually preferred. An example of the workpiece is a case of the laptop computer whose size is of about 11˜15 inches. Of course, for smaller workpiece, such as cases of cellular phone or MP3, two or more workpieces every time but distant form each other are preferred.

Please refer to FIGS. 1A and 1B, a sputtering system 1 of the present invention comprises a first and a second sputtering sources 104,106 are presented to make a film uniformly deposited on a workpiece having non-planar surfaces, particularly, to a 3-dimensional workpiece having planar surface and vertical surfaces such as sidewall of a recess, or outer surface of boss bolt.

The first sputtering source 104, atop the workpiece carrier 102 is of about in parallel, are sputtered by plasma to form a film mainly on the planar portions of the workpiece 2 in comparison with the others, which are the riser of the stairs or the surfaces of the boss bolt.

Referring to FIG. 1B, the second sputtering source 106, surrounded the first sputtering source 104, are set inclines inward rather than in parallel. The second sputtering source 106 is fixed by a bolt and a nut and disposed on a second target seat 109, which inclines a predetermined angle θ with respect to the horizontal. The angle θ is adjustable and depends on the size of the workpiece and the shortest distance between the second sputtering source 106 and the workpieces. For example, in the preferred embodiment of the present invention, the angle θ is about 15˜55 degree for a case of a laptop computer having a width of about 11 inches. Besides, the workpiece carrier 102 is elevated until the bottom of the workpiece 2 is about the same position as the bottom of the second sputtering source 106 so that the second sputtering source 106 can be served as a normal target of the vertical surface for improving the coated film uniformity. Of course, the second sputtering source 106 has a height which is larger than the height of vertical surface of the workpiece.

The first sputtering source 104 includes a metal material as a target disposed on a first target seat 108. Similarly, the second sputtering source 106 includes a metal material as a target disposed on the second target seat 109. As is shown, the first and the second sputtering source 104,106 are hollow rectangular in shape, besides, the first sputtering source 104 is arranged in the intermediate zone of the second sputtering source 106. The shapes of the first and the second sputtering source 104,106 also can be replaced by the other types, such as like a donut or a compact disk, which is obvious to one ordinary skill in the art.

The power for the first and the second sputtering source 104,106 are independently connected to a first power supply 11 and a second power supply 13 and thus they can be adjusted decoupled according to the sizes and a number of the workpieces 2 to optimize the quality of the film.

The plasma distribution in the sputtering chamber 10 is usually non-uniform depends on the relative positions. As a result, the film deposited on surfaces of the workpiece is usually non-uniform. A rotating device 1021 installed under the workpiece carrier 102 may assist in achieving more uniform film.

To improve the sputtering yield, and the sputtering rate, first magnets 105 and second magnets 107 are respectively, near or surrounded the first sputtering source 104 and the second sputtering source 106 to trap the secondary electrons emitted from the sputtering source. One of two first magnets 105 surrounds the inner sidewall of the first sputtering source 104 and the other surrounds the outer sidewall. Similarly, one of two second magnets 107 surrounds the upper sidewall of the first sputtering source 106 and the other surrounds the lower sidewall. The polarities of first magnets 105 and second magnets 107 are shown in FIGS. 1A and 1B. As a result, the opportunities of the collision in between the electrons and the gas molecules increase, i.e., more ions would be generated to collide with the targets.

In addition, inside the vacuum chamber 10, a mask 103 with a predetermined pattern may be provided to deposit a film having a corresponding pattern onto the workpiece 2. The mask 103, shape of which is designed to correspond with the surface profile of the workpiece 2, is closely attached on the workpiece 2 during a sputtering process to prevent the region near the edge of the mask pattern but under the mask from coating.

The target materials of the first sputtering source 104 and the second sputtering source 106 may be the same or different depends on the requirement. In a preferred embodiment, the materials are selected from a group consisting of copper, Al—Mg alloy, stainless steel and silicon for depositing an EMI film.

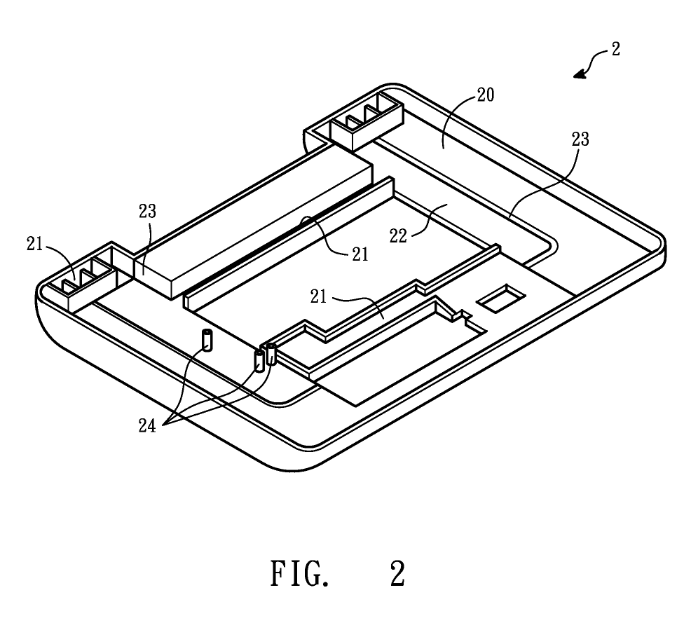

Since the cases of the laptops or the cellular phones are usually with a streamline profile rather than a bulky and to house elements such as motherboard, hard disk drive, optical drive, heat dissipation module, the inner surfaces of the cases have a plurality of the recesses, boss bolts, grooves are common. Thus, the surface profile of the workpieces to be deposited a film includes planar surfaces and vertical surfaces, such as sidewalls. FIG. 2 shows an example of the workpiece including, recesses 20, grooves 21, inclined planes 22, steps 23, and bolts 24. Therefore, the second sputtering source 106 in accordance with the present invention is mainly to cope with any shapes of sidewalls of the workpiece from all aspects.

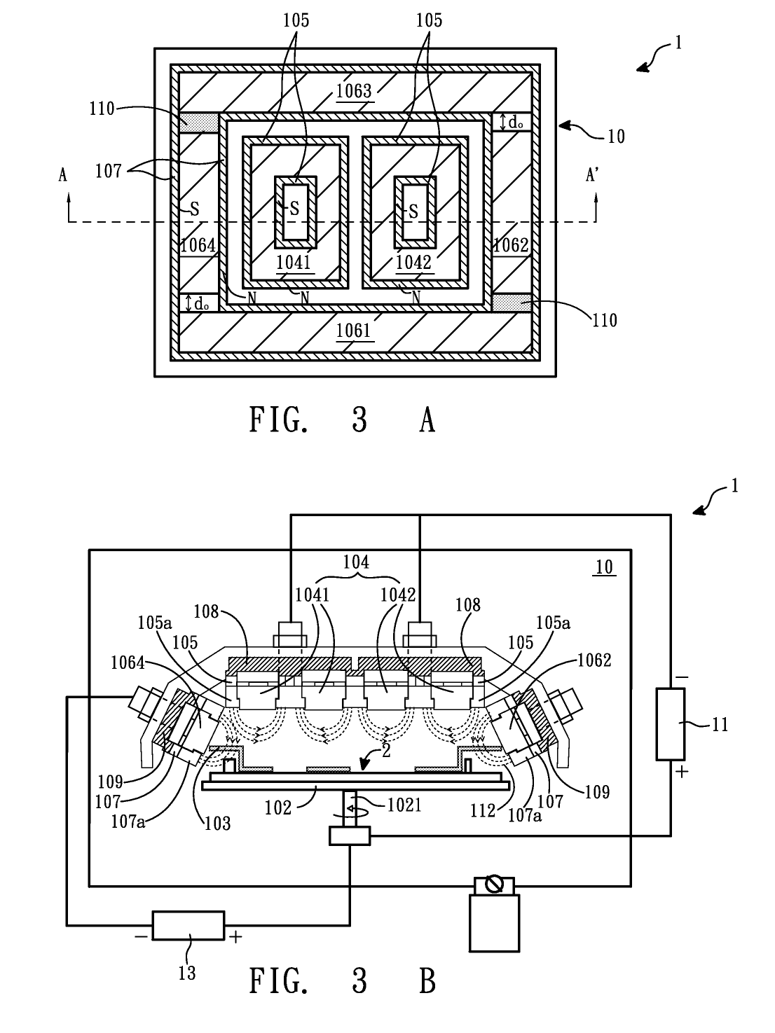

Please turn to the FIGS. 3A and 3B, which show respectively, a top view and a cross-sectional view, viewing from a line A-A′ cut from FIG. 3A of an another preferred embodiment. Rather than single target for each sputtering source, the first sputtering source 104 includes two first targets 1041˜1042. Each first target is equipped with a pair of first magnets 105, one of which surrounds an inner sidewall and the other surrounds an outer sidewall.

Similarly, the second sputtering source 106 is composed of four rectangular targets 1061 to 1064, each of which is mounted on the second target seat 109. The four rectangular targets 1061 to 1064 do not form a closed loop but have an interval d₀ in between, wherein the interval d₀ between the nearest second targets is of about 0.1 to 15 mm, but more preferably is of about 0.5 to 3 mm, according to a magnetic field created by the second magnet 107.

The sputtering system may also use to form a reactive sputtering film, which uses metal as target and reacting gas such as oxygen or nitrogen to form an oxide compound or nitrogen compound. For reactive sputtering, the set of targets 1061, 1064 and the other set of targets 1062, 1063, which are alternately applied positive voltage and negative voltage, respectively, are separated from each other by placing two insulator sheets 110 in diagonal positions of the intervals.

The four second targets 1061˜1064 disposed roughly surround the first targets 1041, 1042. The plane normal of each the second target seat 109 inclines an angle θ with respect to the horizontal.

Alternatively, in accordance with a third preferred embodiment of the present invention, as shown in FIG. 3C, the second sputtering source 106 is assembled by eight targets 1061˜1068. Four rectangular targets 1061˜1064 as edges and four round corner targets 1065˜1068 connected therebetween as four corners form a closed-loop second sputtering source 106. The length of the rectangular targets 1061˜1064 and radius of the round corner targets are specify designed to match the outer profile of the workpiece so as to improve film uniformity of the workpiece 2, particularly, to the corners of the workpiece.

An upper and a lower magnet sets are disposed, respectively, on an upper and a lower sidewalls of targets 1061˜1068. The magnet sets are composed of multiple small magnets which are disposed side by side, forming a shape of closed-loop, so that the magnetic path 111 is unique and enclosed around all targets 1061˜1068. The ferromagnetic material 107a further are placed on the sidewalls of all targets so that the magnetic flux 112, which is generated by magnet sets, is guided across the normal surface of the targets, as shown in FIG. 3C.

Both of first targets 1041˜1042 are connected with the same power, the first power supply 11. Similarly, all of the second targets 1061˜1064 are connected with the second power supply 13.

To deposit a composite or alloy film onto the workpiece, a sputtering source may use different target materials. In addition, the rotating device 1021 is provided to rotate the workpiece 2 during sputtering process so that different kinds of materials are mixed well. For depositing an EMI film, the foresaid materials are selected from the group consisting of copper, Al—Mg alloy, stainless steel and Si.

Surely, the targets in 1041˜1042 or 1061˜1064, may connect to several power supplies, e.g. one by one or two by one so that the power for each target can be adjust independently. Another benefit is the composition of the alloy can be controlled easily.

With the inclined second sputtering source 106 aided the first sputtering source 104, a 3-D sputtering is easier to approach. The experimental results shows that the uniformity of the film formed on recesses, grooves, inclined planes, steps, and bolts are improved substantially. Shadow effect can be drastically diminished except those recesses or groves with an aspect ratio thereof more than five.

Moreover, since the first and the second sputtering sources 104, 106 are composed of a plurality of the targets, which provide more degree of freedoms so that a composite film or composition of an alloy film can be prepared easily, and the convenience of changing targets because anyone of these targets can be deposed and changed independently.

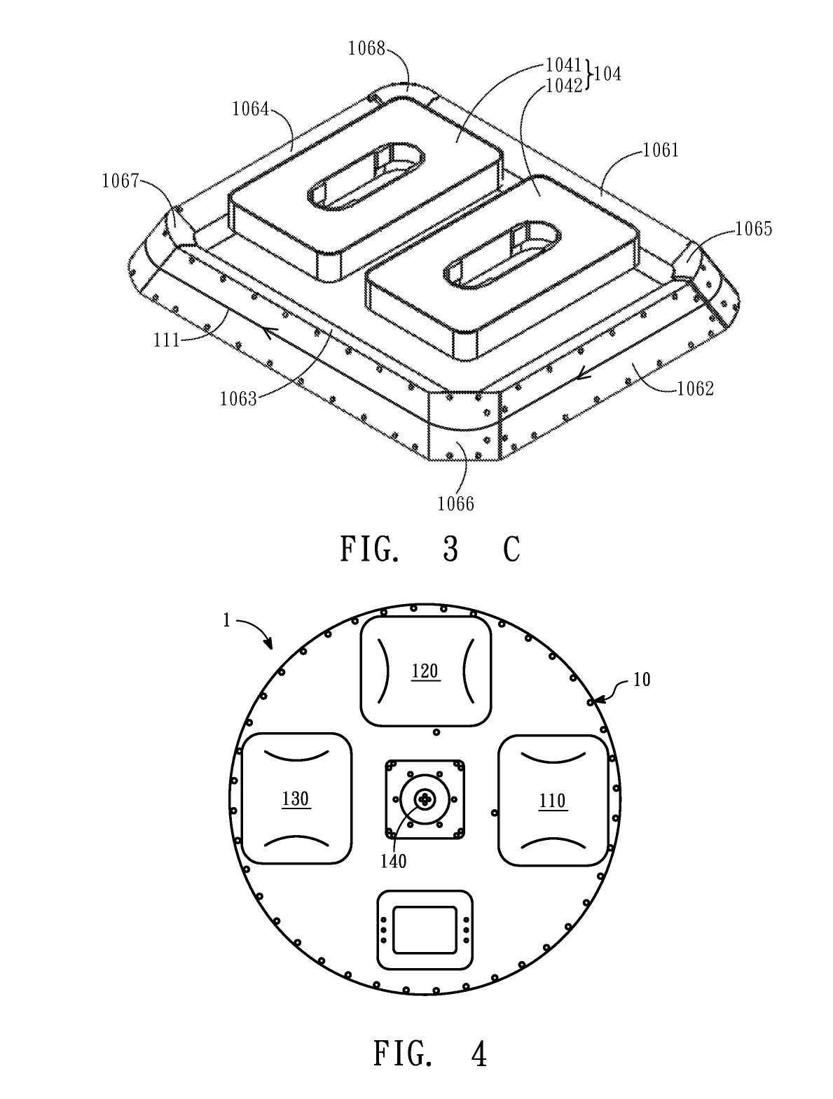

To in-situ deposit a stacking film, as shown in FIG. 4, a vacuum chamber 10 has three reactive rooms 110˜130, each of which has both first and second sputtering sources 104,106 as aforementioned. A turntable device 140 is installed to transfer the workpieces from one reactive room to another.

While the preferred embodiment of the invention has been illustrated and described, it will be appreciated that various changes and modifications can be made therein without departing from the spirit and scope of the invention.

What is the claimed is:

1. A sputtering system to form films onto a 3-dimensional workpiece comprising:
a vacuum chamber having a carrier for supporting a workpiece to be coated having a first planar surface and a second surface which substantially perpendicular to said first planar surface;
a first sputtering source being sputtered by plasma to deposit said films mainly onto said first planar surface;
a second sputtering source composed of a plurality of second targets which are assembled to form a round corner rectangular loop which surrounded said first sputtering source, and said second sputtering source are set inclines inward a predetermined angle with respect to the horizontal and said second sputtering source having a predetermined height larger than the height of said second surface; an upper and a lower magnet sets disposed, respectively, on an upper and a lower sidewalls of said second targets having a shape of loop so as to generate a magnetic path which is unique and enclosed around said second targets.

2. The sputtering system according to claim 1, wherein said first sputtering source and said second sputtering source are hollow rectangular in shape, and said sputtering system further comprising two first magnets surrounding an inner sidewall and an outer sidewall of said first sputtering source.

3. The sputtering system according to claim 1 wherein said first sputtering source comprises a plurality of first targets and each of them is hollow rectangular in shape and the sputtering system further comprising a plurality of pairs of said first magnets, each pair of first magnets surrounded an inner sidewall and an outer sidewall of said first target.

4. The sputtering system according to claim 1 wherein said second sputtering source composed of four rectangular targets, which surrounded said first sputtering source but have an interval in between, wherein two insulator sheets are placed in diagonal positions of the intervals for reactive sputtering.

5. The sputtering system according to claim 1 wherein said second sputtering source composed of four rectangular targets as edges and four round corner targets connected therebetween as four corners to form closed-loop said second sputtering source.

6. The sputtering system according to claim 5 further comprising the rotating device to rotate the workpiece during sputtering process so that different kinds of materials are mixed well to deposit a composite or alloy film.

7. The sputtering system according to claim 1, said workpiece carrier is elevated until the bottom of the workpiece is about the same as the position as the bottom of said second sputtering source so that said second sputtering source can be served as a normal target of the vertical surface for improving the coated film uniformity.

8. The sputtering system according to claim 1, wherein the predetermined angle θ is about 15˜55 degree.

9. The sputtering system according to claim 1 further comprising a mask with a predetermined pattern so as to deposit said films having a corresponding pattern onto the workpiece.

10. The sputtering system according to claim 1, wherein said vacuum chamber further comprising a plurality of reactive rooms having both said first and second sputtering sources in each, and said sputtering system further comprising a turntable device installed to transfer the workpiece from one reactive room to another so as to in-situ deposit stacking film.
